(19) United States
(12) Patent Application Publication
(10) Pub. No.: US 2025/0231231 A1
(43) Pub. Date: Jul. 17, 2025

(54) SEARCH FUNCTION WITH DEVICE MODELING

(71) Applicant: Keithley Instruments, LLC, Solon, OH (US)

(72) Inventor: Connor Andrew Hemmelgarn, Cleveland Heights, OH (US)

(73) Assignee: Keithley Instruments, LLC, Solon, OH (US)

(21) Appl. No.: 18/982,752

(22) Filed: Dec. 16, 2024

Related U.S. Application Data
(60) Provisional application No. 63/620,350, filed on Jan. 12, 2024.

(51) Int. Cl. G01R 31/26

(52) U.S. Cl. CPC G01R 31/2621

(57) ABSTRACT

In some implementations, a method may include acquiring a first plurality of measurements for the DUT, where the test and measurement instrument is not configured with the characteristic of the DUT and the first plurality of measurements may include measurements for the characteristic. In addition, the method may include determining an exponential model of the DUT based on the first plurality of measurements, where the exponential model is representative of behavior of the DUT. The method may include acquiring a second plurality of measurements different from the first plurality of measurements, where the second plurality of measurements may include measurements for the characteristic of the DUT. Moreover, the method may include verifying the exponential model based on the second plurality of measurements. Also, the method may include adjusting the behavior of the test and measurement instrument based on the verified exponential model of the DUT.

### CROSS-REFERENCE TO RELATED APPLICATION

This application claims benefit of U.S. Provisional Application No. 63/620,350, titled “SEARCH FUNCTION WITH DEVICE MODELING,” filed on Jan. 12, 2024, the disclosure of which is incorporated herein by reference in its entirety.

### TECHNICAL FIELD

Examples of the present disclosure generally relate to test and measurement instruments, and more particularly to a search function for a test and measurement instrument.

### BACKGROUND

In device testing, search functions are used to find specific device parameters. An example search function includes finding the threshold voltage for a metal-oxide-semiconductor field-effect transistor (MOSFET), which is the necessary voltage between the gate and source of the MOSFET for the MOSFET to be “on” and conducting (defined by a specific current level). The search function is provided with a target current and a range of voltage in which to search for the threshold voltage at which the MOSFET conducts the target current. Any approach to finding the parameter has to source voltages iteratively to adjust the conducted current closer to the target current, have a final current reading that is sufficiently close to the target current, and be able to complete the search in a timely manner.

One solution involves using a binary search algorithm. The binary search algorithm iteratively performs measurements at midpoints between a lower bound and an upper bound of a previous measurement. When using a binary search algorithm, the first measurement is the midpoint between the lower bound and the upper bound. If the current is lower than the target current, the threshold voltage must be higher than the midpoint. The midpoint then becomes the lower bound, the domain space of possible results is halved. The next measurement is taken at midpoint again and will again halve the domain space. As each iteration halves the resolution, the number of possible results for a binary search is 2^{N} where N is the number of iterations, and the resolution is the reciprocal: ½^{N}.

While the binary search algorithm is particularly robust, the advantages of the binary search algorithm are its simplicity and its ease of computation that facilitates higher sampling frequencies. However, for the measurements needed in these applications to overcome noise, measurement time for the binary search algorithm is relatively long (in the order of milliseconds), and thus computation time is negligible. Additionally, accuracy is the goal, but adding another measurement to further narrow down resolution would add more time to the search. There are also assumptions made by the binary search algorithm that go unnoticed in some applications but become apparent in other applications. The binary search algorithm assumes that a sourced voltage value is the exact measured value on the device under test (DUT), which is not the case. The binary search algorithm has no method by which to account for this error. Furthermore, when the binary search algorithm erroneously decides that the resultant voltage is less or more than a specific voltage it had believed to test, the binary search algorithm will never be able to settle on the correct side of the specific voltage that it had meant to test for: errors are non-recoverable.

The binary search algorithm is functionally a one-dimensional algorithm, shifting the voltage left or right along the x-axis, depending on the state of the outcome measurement being above or below the target. The precision current measurement on a continuous domain of values is rendered into a binary value to act upon: above or below target. In an example execution of a binary search, the process was readily shown on a single x-axis for control variable of voltage. This example execution of a binary search works well when no assumptions can be made about the functional relationship between the input and output variable, aside from being an injective (one to one) function.

### SUMMARY

A system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions.

In one general aspect, a method may include acquiring a first plurality of measurements for the DUT, where the test and measurement instrument is not configured with the characteristic of the DUT and the first plurality of measurements may include measurements for the characteristic. The method may also include determining an exponential model of the DUT based the first plurality of measurements, where the exponential model is representative of behavior of the DUT. The method may furthermore include acquiring a second plurality of measurements different from the first plurality of measurements, where the second plurality of measurements may include measurements for the characteristic of the DUT. The method may in addition include verifying the exponential model based on the second plurality of measurements. The method may moreover include adjusting the behavior of the test and measurement instrument based on the verified exponential model of the DUT. Other embodiments of this aspect include corresponding computer systems, apparatus, and computer programs recorded on one or more computer storage devices, each configured to perform the actions of the methods.

In one general aspect, a test and measurement system may include a test and measurement instrument having one or more ports to connect the test and measurement instrument to a device under test (DUT). The test and measurement system may include memory. The test and measurement system may include one or more processors configured to execute code stored on the memory, where the code causes the one or more processors to: acquire a first plurality of measurements for a parameter of the DUT, where the test and measurement instrument is not configured with the parameter of the DUT; determine an exponential model of the parameter of the DUT based the first plurality of measurements; acquire a second plurality of measurements for the parameter of the DUT, where the second plurality of measurements are different from the first plurality of measurements; verify the exponential model based on the second plurality of measurements; and adjust behavior of the test and measurement instrument based on the verified exponential model of the DUT. Other embodiments of this aspect include corresponding computer systems, apparatus, and computer programs recorded on one or more computer storage devices, each configured to perform the actions of the methods.

In one general aspect, a test and measurement system may include a test and measurement instrument having one or more ports to connect the test and measurement instrument to a device under test (DUT). The test and measurement system may include memory. The test and measurement system may include one or more processors configured to execute code stored on the memory, where the code causes the one or more processors to: determine a model of a parameter of the DUT based on three measurements of the parameter by the test and measurement instrument; verify the model based on a fourth measurement and a fifth measurement of the parameter by the test and measurement instrument; and adjust behavior of the test and measurement instrument for the parameter based on the verified model of the DUT. Other embodiments of this aspect include corresponding computer systems, apparatus, and computer programs recorded on one or more computer storage devices, each configured to perform the actions of the methods.

These and other aspects may be understood with reference to the following detailed description.

### BRIEF DESCRIPTION OF THE DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1 shows a test and measurement system 100 including a test and measurement instrument, according to some examples.

FIGS. 2-6 illustrate the parameters for measurements to characterize a device using the search function as described herein, according to some examples.

FIG. 7 is a flowchart of a process of the search function, according to some examples.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the description or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

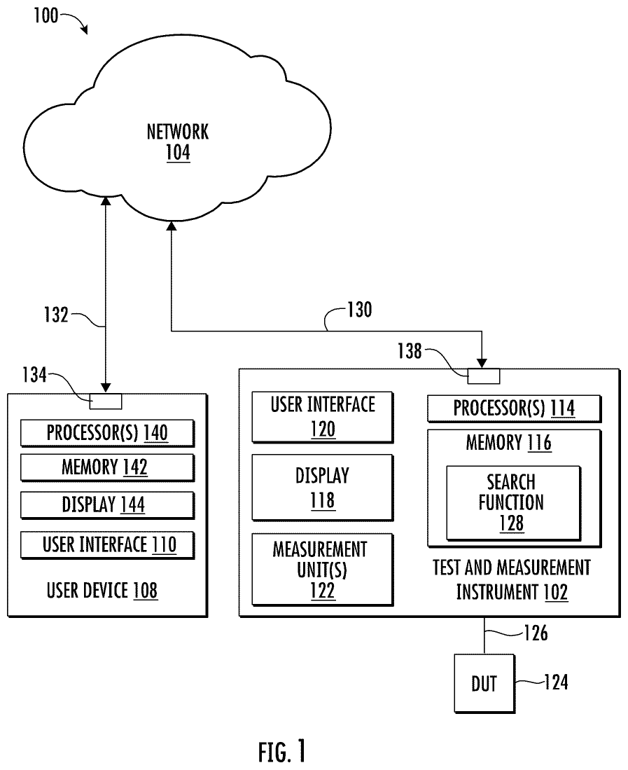

FIG. 1 shows a test and measurement system 100 including a test and measurement instrument, referred to as test and measurement instrument 102, connected through a network 104 to a user device having a user interface 110 in accordance with embodiments of the disclosure. The measurement data generated by the test and measurement instrument 102 is communicated over the network 104 and accessible by the user device 108. Accessing the measurement data includes streaming, viewing, and analyzing the data using the user interfaces 110 of the user device 108 to configure and modify configurations for measurements, including various data transformations of the measurement data from the test and measurement instrument 102. In some examples, the user can use the user device 108 to modify parameters and/or any configuration settings for the search function described herein. In further examples, the user can use the user device 108 to visualize a model of the device characteristic and/or parameter, as further described herein.

In the test and measurement system 100 of FIG. 1, the test and measurement instrument 102 includes one or more processors 114, a memory 116, a display 118, and a user interface 120, which may exist as part of a touch-screen display or take the form of control knobs and other user input devices. The one or more main processors 114 are configured to execute instructions from memory 116 to implement any methods and associated steps defined by such instructions to control the overall operation of the test and measurement instrument 102. One or more measurement units 122 in the test and measurement instrument 102 perform the main functions of measuring parameters and other qualities of signals from a device under test (DUT) 124 being tested or analyzed by the test and measurement system 100. Some measurements performed by the one or more measurement units 122 include measuring voltage, current, and power of input signals in the time domain, as well as measuring characteristics of the signals in the frequency domain. The one or more measurement units 122 represent any components for performing any measurements that are typically performed on test and measurement instruments. The test and measurement instrument 102 is coupled to the DUT 124 through a connection 126, such one or more cables or other suitable types of electrical connections.

In some examples, the memory 116 includes instructions to implement the search function 128 and the model derived from the search function 128. Accordingly, the one or more main processors 114 of the test and measurement instrument 102 are configured to execute instructions from memory 116 to implement the search function 128. Further details regarding the search function 128 and the corresponding model are described herein.

Testing the DUT 124 by the test and measurement instrument 102 generates acquired measurements, which may be transmitted through the network 104 to the user device 108. For these transmissions, a network port 138 of the test and measurement instrument 102 is coupled through a connection 130 to the network 104 and further through a network connection 132 to the user device 108. In this way, the network port 138 allows the test and measurement instrument 102 to transmit, over the network 104, acquired measurements to the user device 108. In some examples, the test and measurement instrument 102 is coupled to the user device 108 directly, and thus, the test and measurement instrument 102 directly transmits acquired measurements to the user device 108.

Once the acquired measurements from the test and measurement instrument 102 have been transferred or uploaded to the user device 108, users may, through configuration of the user device 108, access the acquired measurements, as well as any other information related to the acquired measurements, to work with and analyze different aspects of the acquired measurements. The user device 108 is coupled via port 134 through network connection 132 and the network 104 to the test and measurement instrument 102. The user interface 110 of the user device 108 may be configured to access, display, and share the acquired measurements.

As mentioned above, although the user device 108 is the only of the user devices illustrated in FIG. 1, the system 100 can include any number of user devices having similar components and corresponding user interfaces 110. The user device 108 includes one or more processors 140, a memory 142, a display 144, and the user interface 110. The one or more processors 140 are configured to execute instructions from memory 142 to implement methods defined by such instructions and thereby control the overall operation of the user device 108. The display 144 may be any suitable type of digital screen such as an LED display or a LCD, or any other suitable type of display. The display 144 renders or displays windows generated by the user interface 110 for viewing by a user of the user device 108. The user interface 110 may include a keyboard, mouse, touchscreen, or any other suitable controls employable by a user to interact with the user device 108.

In the test and measurement system 100, the network 104 may include a closed network, meaning a network available only to users of a particular company, building, or private network, or may include an open network, for example including the Internet, may be a virtual private network, and may be other suitable types of network architectures as well. The network connections 130 and 132 between components of the test and measurement system 100 may be any suitable type of wired or wireless network, including near-field communications (NFC) connections, infrared (IR) connection, Bluetooth® connections, Wi-Fi connections, Ethernet connections, and so on.

The present disclosure describes a search function (e.g., search function 128 of FIG. 1) for device characterization. The characterization of a device is done to find parameters used in the design process of circuits to model behavior. In the manufacturing process, devices are tested (e.g., DUTs) to ensure conformity to published specifications. When testing starts, the exact behavior of the DUT is unknown. However, the general pattern of behavior is intrinsic to the DUT. For example, in metal-oxide-semiconductor field-effect transistors (MOSFETs), at lower gate-to-source voltages (Vgs), increases in Vgs exponentially increase the drain-to-source current (Ids). Current does not substantially increase until after the Vgs passes the threshold voltage (Vth): a critical parameter. The value for Vth varies as a result of processing irregularities and impurities.

The present disclosure is that if the general relationship between Vgs and Ids is known to be exponential, then preliminary measurements can be used as data points to define an exponential curve for a model of the device. The model is then used to determine the approximate value for Vth, which is measured and then used to further refine the model. While the present disclosure involves exponential functions, the present disclosure is not limited to exponential functions and can apply to other mathematical functions, such as polynomial functions, representing characteristics of the DUT.

The process of fitting an exponential curve to the data points is a form of statistical regression. However, unlike a linear regression or a higher order polynomial regression, an exact formula is not readily derivable. The present disclosure involves continually developing an exponential curve of the form ƒ(x)=A+Be^{Cx} to fit the provided data points using regression and approximation. The initial approximate values for the parameters A, B, C can be determined using linear approximation. However, for a near exact fit to the data points that this process requires, the exponential curve is further tuned by iteratively adjusting the parameters to minimize error between the model and data points.

Instead of using the data from a single point to determine the next measurement point, the present disclosure involves a search function using multiple data points to model the device, thereby increasing accuracy. As the model disclosed in the present disclosure is a continuous function, the determined next measurement can be at any value, not limited to a discrete list of possible values as a binary search was. This increase in accuracy also reduces the number of measurement iterations needed to reach the target point for the parameter. While the present disclosure involves a continuous function, the present disclosure can apply to other types of functions.

As a curve requires three points, the search function of the present disclosure makes its first three measurement points the same as a binary search function. Then, an exponential curve is fit to the data. The curve is used to determine the fourth measurement point. The measurement is in the general area of the target value. To make the next approximation as accurate as possible for the target, only the closest three data pairs are used to make the curve, so that the approximation is localized to the target area. This process is done iteratively: measuring closer to the target, making a model of the local data points, and measuring again until sufficiently close to the target.

As mentioned above, a DUT (e.g., DUT 124) can be coupled to a test and measurement instrument (e.g., test and measurement instrument 102) for testing. Before the test and measurement instrument takes any measurement, the test and measurement instrument does not have any information for the DUT. In some examples, the test and measurement instrument may have information from the user regarding the DUT, such as the device type for the DUT (e.g., diode, MOSFET). In some examples, the test and measurement instrument may have the desired characteristic and/or parameter to be measured for the DUT. For example, the user may want to determine the Vgs threshold for the MOSFET, where the DUT is a diode. Accordingly, some information regarding the DUT is unknown to the test and measurement instrument, and the user desires to determine the information regarding the DUT using the test and measurement instrument. Accordingly, the test and measurement instrument needs further information regarding the desired characteristic and/or parameter of the DUT in order to perform further testing of the DUT. However, once the test and measurement instrument determines the information related to the desired characteristic and/or parameter of the DUT, the test and measurement instrument adjusts its behavior to continue testing the DUT based on the desired characteristic and/or parameter and based on the model of the desired characteristic and/or parameter.

Because the test and measurement instrument does not have information regarding the characteristic and/or parameter of the DUT, the test and measurement instrument begins to determine the characteristic and/or parameter of the DUT by the search function (e.g., search function 128 of FIG. 1) described herein. The test and measurement instrument begins the search function by making three measurements for the desired device characteristic and/or parameter. For each of the three measurements, the test and measurement instrument performs the search function by looking for a particular device characteristic and/or parameter based on a desired result within a lower bound and an upper bound from a previous measurement iteration. In some examples, the test and measurement instrument determines that the test and measurement instrument has not made a prior measurement and thus uses a predetermined lower bound and upper bound. In some examples, the lower bound and upper bound can be set by the user before the search function begins.

FIG. 2-6 illustrate the parameters for measurements to characterize a device using the search function as described herein, according to some examples. As an example, when performing the search function of the present disclosure for an example device, such as a diode, the search function looks for a first measurement of voltage between 0.00 Volts (i.e., the lower bound) and 1.00 Volts (i.e., the upper bound) such that the diode conducts 10 mA. Accordingly, for Measurement 1 of the search function of the present disclosure, the search function, via the test and measurement instrument, uses a Source Voltage of 500 mV, which results in a measured current of 0.503 mA.

Because the first measurement results differently than desired, the test and measurement instrument adjusts the lower bound and upper bound for a next measurement based on the prior measurement. For example, as the measured current of Measurement 1 was less than the target current of 10 mA, the test and measurement instrument determines that the necessary voltage is greater than 500 mV and less than 1.00 V, shown on the X-axis in FIG. 2, that is, the resolution is 500 mV. Accordingly, the test and measurement instrument determines the lower bound of the next measurement to be 500 mV and the upper bound of the next measurement to be 1.00V.

The test and measurement instrument adjusts the Source Voltage of the next measurement to a midpoint, or 750 mV, between the adjusted lower bound and upper bound of the next measurement. Accordingly, Measurement 2 of the search function of the present disclosure uses the Source Voltage of 750 mV, resulting in a measured current of 121 mA.

Because the Measurement 2 still results differently than desired, the test and measurement instrument adjusts the lower bound and upper bound for a next measurement based on the prior measurement. As the measured current of Measurement 2 was greater than the target current of 10 mA, the necessary voltage is greater than 500 mV and less than 750 mV, as shown on the X-axis of FIG. 3, that is, the resolution is adjusted to 250 mV, or a half of the previous 500 mV. Accordingly, the test and measurement instrument determines the lower bound of the next measurement to be 500 mV and the upper bound of the next measurement to be 750 mV, as illustrated in FIG. 3.

The test and measurement instrument adjusts the Source Voltage of the next measurement to midpoint, or 625 mV, between the adjusted lower bound and upper bound of the next measurement. Accordingly, Measurement 3 of the search function of the present disclosure uses the Source Voltage of 625 mV, resulting in a Measured Current of 8.5 mA.

At this time since the search function of the present disclosure has three data points, a curve can be fit to the three data points. Accordingly, the test and measurement instrument determines a model based on the three data points (e.g., Measurement 1, Measurement 2, and Measurement 3). In some examples, the model is an exponential function model. In further examples, the exponential function is based on ƒ(x)=A+Be^{Cx}. Accordingly, the test and measurement instrument determines the model such that the exponential model fits the provided data points using regression and approximation. In such examples, the test and measurement instrument determines the coefficients A, B, and C for the exponential function.

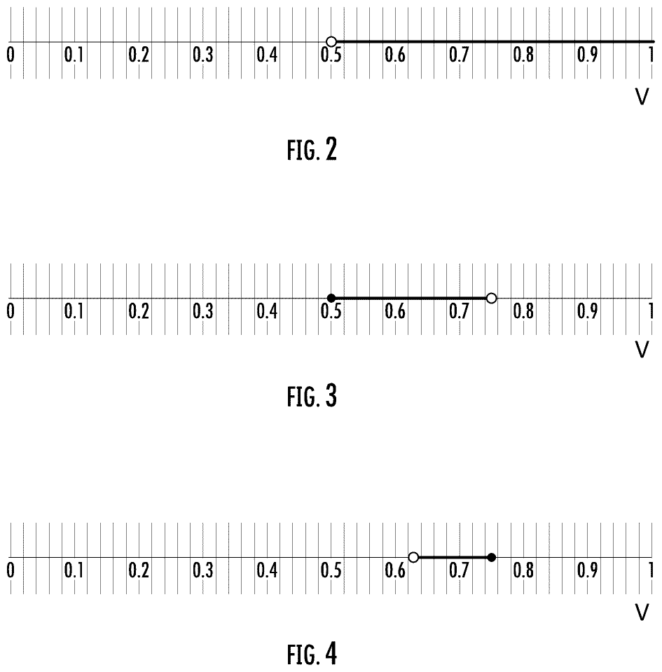

To verify the accuracy of the model, the test and measurement instrument performs additional measurements. Because the third measurement still results differently than desired, the test and measurement instrument adjusts the lower bound and upper bounds for a next measurement based on the prior measurement. As the measured current of Measurement 3 was less than the target current of 10 mA, the necessary voltage is greater than 625 mV and less than 750 mV, as shown on the X-axis of FIG. 4, that is, the resolution is adjusted to 125 mV, or a half of the previous 250 mV. Accordingly, the test and measurement instrument determines the lower bound of the next measurement to be 625 mV and the upper bound of the next measurement to be 750 mV.

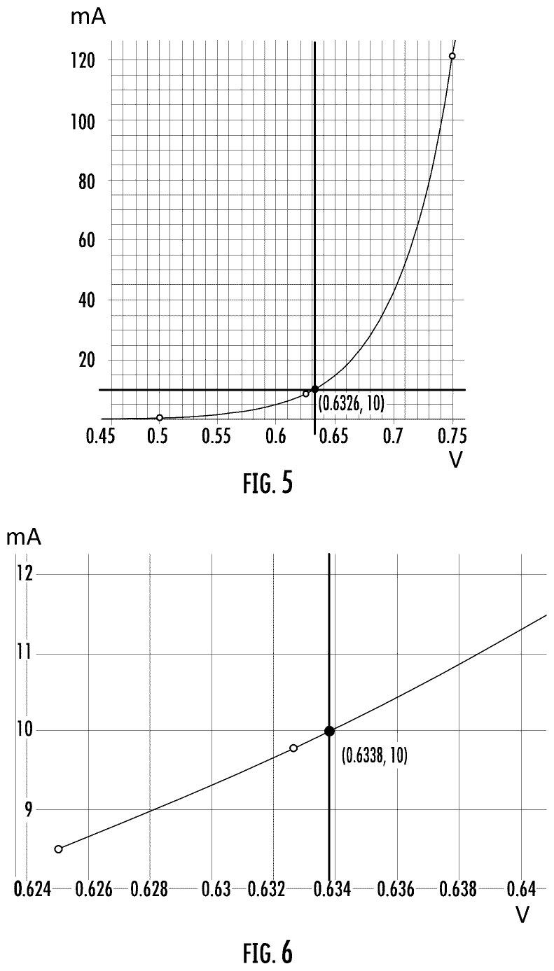

The test and measurement instrument adjusts the Source Voltage of the next measurement to a point between the adjusted lower bound and upper bound of the next measurement. At this point, the test and measurement instrument uses a different resolution for the next measurement as compared to the resolution used for the previous three measurements. In some examples, the test and measurement instrument uses a resolution for determining the next measurement point based on the resolution of the test and measurement instrument. Accordingly, based on the above example, using three points and linear approximation, the next measurement point can be approximated to 632.6 mV (shown as a black circle) for a desired current of 10 mA based on the exponential model and the resolution of the test and measurement instrument, as illustrated in FIG. 5. The search function of the present disclosure performs Measurement 4 having a Source Voltage of 632.58 mV, which results in a Measured Current of 9.79 mA.

The test and measurement instrument uses the results of Measurement 4 to further tune the exponential curve to fit the current results of the search function. In some examples, the test and measurement instrument adjusts the values of A, B, and C for the exponential formula ƒ(x)=A+Be^{Cx} to account for Measurement 4. Accordingly, the test and measurement instrument adjusts the model of the device parameter to fit the measurements made thus far. For example, the test and measurement instrument is looking for the threshold voltage (Vth), which is an example device parameter for a transistor, and thus the model describes the device's measured drain current (Ids) as a function of the gate-to-source voltage (Vgs). In such example, the threshold voltage is the amount of applied Vgs to get a specific Ids such that the device is considered “on” and conducting. Accordingly, the model representing Ids as a function of Vgs is used to find the threshold voltage for a specific Ids, and thus the test and measurement instrument adjusts the model representing Ids as a function of Vgs. Consequently, the test and measurement instrument can use the model to accurately find the desired device parameter (in this example, Vth) and change its behavior based on the model.

As described, starting after a first verification measurement, the test and measurement instrument determines whether or not to continue the search. In some examples, the test and measurement instrument can base the determination of whether to continue the search based on the difference of the most recent measurement to the desired target. For example, the test and measurement instrument determines the difference between the measured current of 9.79 mA for Measurement 4 and the target current of 10 mA is 0.21 mA. In some examples, the difference threshold for continuing the search can be predetermined or can be set by the user.

In the present example, the test and measurement instrument determines to continue the search because the difference between the measured current and the target current is 0.21 mA, which is greater than the difference threshold for the model, and further verification of the model is needed to ensure the accuracy of the model. Accordingly, the search function looks for another value for a Source Voltage which results in the target current of 10 mA. Because the previous measurement still results differently than desired, the test and measurement instrument adjusts the lower bound and upper bounds for a next measurement based on the prior measurement. Like with the previous measurement, the test and measurement instrument uses a resolution for determining the next measurement point based on the resolution of the test and measurement instrument. As the measured current of Measurement 4 was less than the target current of 10 mA, the necessary voltage is greater than 632.58 mV and less than 750 mV.

Accordingly, based on the above example, the next measurement point can be approximated to 633.8 (shown as a black circle) for a desired current of 10 mA based on the exponential model and the resolution of the test and measurement instrument, as illustrated in FIG. 6. The search function performs Measurement 5 using a Source Voltage of 633.8 mV, resulting in a Measured Current of 10.017 mA.

As described, with every iteration of the search function, the test and measurement instrument determines whether or not to continue the search. With a target current of 10 mA and a reading of 10.017 mA, the search function only has an error of 17 μA on its fifth iteration.

While another iteration of the search function of the present disclosure may yield a measurement numerically closer to the target, it is important to remember the accuracy of the instrument itself. At the 100 mA range, the test and measurement instrument used to conduct these measurements has a current measurement accuracy specification of 12 μA (for the reading being about 10 mA).

In the present example, because the measured current of Measurement 5 was greater than the target current of 10 mA, the search function uses the results of Measurement 5 to further tune the exponential curve to fit the current results of the search function. Accordingly, the search function can perform another measurement based on the exponential model and the resolution of the test and measurement instrument. In such case, Measurement 6 uses a Source Voltage of 633.53 mV, which results in a Measured Current of 9.997 mA.

The 0.270 mV adjustment between Measurement 5 and Measurement 6 can be loosely benchmarked against the resolution of 16.25 mV that was attained by a binary search on its sixth iteration.

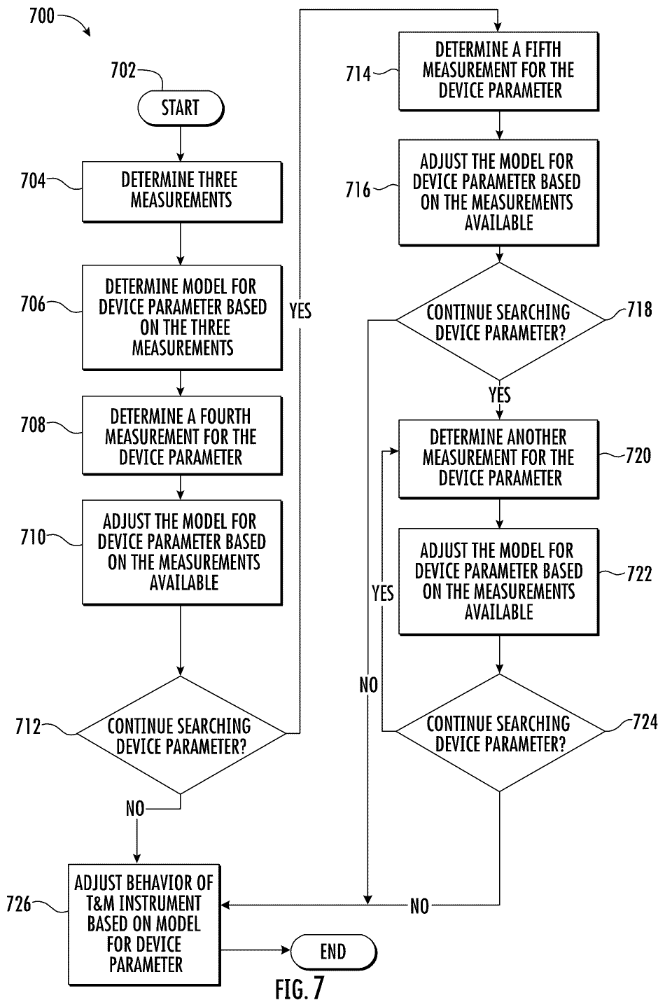

FIG. 7 is a flowchart of a process 700 of the herein described search function, according to some examples. The process 700 can be performed by a test and measurement instrument (e.g., test and measurement instrument 102 of FIG. 1).

The process 700 starts at 702. The process 700 includes operation 704 involving determining three measurements. In some examples, for the first measurement, the test and measurement instrument selects a measurement point between a predetermined upper bound and a predetermined lower bound. In such examples, the predetermined upper bound and the predetermined lower bound are provided by the user or can be based on the limits of the DUT. In some examples, the test and measurement instrument selects a measurement point between an upper bound based on the previous measurement and a lower bound based on the previous measurement. For a first measurement point, because the test and measurement instrument has not made a previous measurement, the test and measurement instrument may use a lower bound and an upper bound as specified by the limits of the DUT. For example, the test and measurement instrument is looking for a threshold voltage for a transistor, and as such, the first measurement point uses a lower bound of 0V and an upper bound of 1V. The three measurements performed during operation 704 can be used to determine any characteristic and/or parameter of the DUT, so long as the measurements performed on DUT by the test and measurement instrument are directed to the same characteristic and/or parameter.

The process 700 includes operation 706 involving determining the model for the device parameter based on the three measurements. As mentioned, when determining the model for the device characteristic and/or device parameter, the test and measurement instrument uses the three measurements for generating a continuous function that represents the operation of the DUT. In some examples, the model is based on an exponential function that represents the device characteristic and/or device parameter of the DUT. The exponential function may use the formula ƒ(x)=A+Be^{Cx}. In such examples, the test and measurement instrument may determine the values of A, B, and C

The process 700 includes operation 708 involving determining a fourth measurement for the device parameter. As mentioned, the fourth measurement adjusts the variables for the device characteristic and/or parameter used in the three measurements of operation 704. In some examples, the test and measurement instrument selects a measurement point based on the resolution of the test and measurement instrument. For example, the resolution of the test and measurement instrument can be defined by the current measurement accuracy specification. In further examples, the test and measurement instrument selects a measurement point between an upper bound based on the previous measurement and a lower bound based on the previous measurement.

The process 700 includes operation 710 involving adjusting the model for device parameter based on the measurements available. In some examples, the test and measurement instrument may adjust the values of A, B, and C of the formula ƒ(x)=A+Be^{Cx} for the model representing the device characteristic and/or device parameter. In some examples, before adjusting the model, the test and measurement instrument determines whether the fourth measurement deviates too much from the model. In such examples, the model has an expected range of deviation for the measurements of the device parameter. If the test and measurement instrument determines that the fourth measurement deviates more than a particular amount from the model, the test and measurement instrument performs another measurement, which can be a repeat of the fourth measurement, and if this repeat measurement still deviates from the model more than the particular amount, the test and measurement instrument indicates an error to the user.

The process 700 includes operation 712 involving deciding whether to continue searching for the device parameter. If the test and measurement instrument decides to not continue searching the device parameter, the process 700 continues to operation 726.

If the test and measurement instrument decides to continue searching the device parameter, the process 700 continues to determine a fifth measurement for the device parameter at 714. In some examples, the test and measurement instrument selects a measurement point based on the resolution of the test and measurement instrument. In further examples, the test and measurement instrument selects a measurement point between an upper bound based on the previous measurement and a lower bound based on the previous measurement.

The process 700 continues to operation 716 involving adjusting the model for device parameter based on the measurements available. In some examples, operation 716 is similar to operation 710 with adjusting the model for device parameter based on the measurements available, including the fifth measurement obtained in operation 714. The test and measurement instrument may adjust the values of A, B, and C of the formula ƒ(x)=A+Be^{Cx} for the model representing the device characteristic and/or device parameter. In some examples, before adjusting the model, the test and measurement instrument determines whether the fifth measurement deviates too much from the model. In such examples, the model has an expected range of deviation for the measurements of the device parameter. If the test and measurement instrument determines that the fifth measurement deviates more than a particular amount from the model, the test and measurement instrument performs another measurement, which can be a repeat of the fifth measurement, and if this repeat measurement still deviates from the model more than the particular amount, the test and measurement instrument indicates an error to the user.

The process 700 continues to operation 718 involving deciding whether to continue searching for the device parameter. If the test and measurement instrument decides to not continue searching the device parameter, the process 700 continues to operation 726.

If the test and measurement instrument decides to continue searching the device parameter, the process 700 continues to determine another measurement for the device parameter at 720. In some examples, the test and measurement instrument selects a measurement point based on the resolution of the test and measurement instrument. In further examples, the test and measurement instrument selects a measurement point between an upper bound based on the previous measurement and a lower bound based on the previous measurement.

The process 700 continues to operation 722 involving adjusting the model for device parameter based on the measurements available. In some examples, operation 722 is similar to operation 710 and operation 716 with adjusting the model for device parameter based on the measurements available, including the most recent measurement obtained in operation 720. The test and measurement instrument may adjust the values of A, B, and C of the formula ƒ(x)=A+Be^{Cx} for the model representing the device characteristic and/or device parameter. In some examples, before adjusting the model, the test and measurement instrument determines whether the most recent measurement deviates too much from the model. In such examples, the model has an expected range of deviation for the measurements of the device parameter. If the test and measurement instrument determines that the most recent measurement deviates more than a particular amount from the model, the test and measurement instrument performs another measurement, which can be a repeat of the most recent measurement, and if this repeat measurement still deviates from the model more than the particular amount, the test and measurement instrument indicates an error to the user.

The process 700 continues to operation 724 involving deciding whether to continue searching for the device parameter. If the test and measurement instrument decides to not continue searching the device parameter, the process 700 continues to operation 726.

If the test and measurement instrument decides to continue searching the device parameter, the process 700 repeats operations 720, 722, and 724 as described above.

The process 700 includes operation 726 involving adjusting the behavior of the test and measurement instrument based on the model for the device parameter. In some examples, the test and measurement instrument considers the model for the device parameter when making further measurements, making measurements for a different parameter for the DUT, or analyzing the model for further information regarding the DUT.

In some examples, when the test and measurement instrument is determining whether to continue searching, the test and measurement instrument can determine whether the most recent measurement for the characteristic and/or parameter deviates from the model for the characteristic and/or parameter by a particular amount. The amount of deviation of the measurement from the model can be pre-configured or can be based on the model. In some examples, the deviation amount based on the model can be based an expected range provided by the model within which the measurement should fall. Should the measurement fall outside the expected range provided by the model, subsequent adjustment of the model based on the measurement may result in model inversion, which is not desired. In some examples, once the test and measurement instrument determines that the most recent measurement deviates from the model by a particular amount, without adjusting the model, the test and measurement instrument performs another measurement and if this new measurement still deviates from the model, then the test and measurement instrument indicates an error. In some examples, the deviation between the measurement and the model can apply to any measurement by the test and measurement instrument after the test and measurement instrument has generated the model.

Using a continuous function to determine a measurement allows the measurement to be taken at any value on a continuous range, rather than from a discrete list of pre-determined values as used by binary search. Using a continuous range of values increases accuracy by measuring as close as possible to the target and not just at the next value on the discrete list.

Using a binary search and its discrete list of values also leads to quantization error. This quantization error happens when a measurement is close to the target and noise determines if the independent value is increased or decreased. This quantization error appears in the data as multi-modal distributions, indicating a process problem where there is only an algorithmic problem. The error would be fixed by a higher accuracy and continuously valued algorithm, improving precision.

Accuracy in a source measure unit (SMU) instrument is highest when the measurement is taken in the smallest possible range. As a binary search does not make an approximation of the next measurement, the SMU cannot set the most optimal range and has to set the highest possible range. In comparison, the search function of the present disclosure can best use the instrument by adaptively setting the range for the highest accuracy.

If a measurement returns a value that deviates far from the model, the search function of the present disclosure can determine that a measurement should be taken again or ultimately return an error indicating that the circuit connection is compromised. As a binary search relies on one measurement, a binary search would continue adjusting the independent variable and return an erroneous value.

Typically, device modeling is done for design work using fully measured parameters to anticipate device behavior in designed circuits. Additionally, the approximations done for design work are typically linear, quadratic, or polynomial and localized to the region that it is designed to be operated in. The use of an exponential function better matches the overall behavior of these devices, which is important for a search function that cannot depend on exact behavior.

The present disclosure involves on-instrument iterative use of exponential regression using preliminary measurements to further refine a device model used to find the target measurement value, improving overall search function accuracy, precision and reducing the number of measurements. Further, refining the device model to find the target measurement value allows the adjustment of behavior of the test and measurement instrument so that further measurements by the test and measurement instrument are more accurate and precise.

In this disclosure, the singular forms “a,” “an,” and “the” include plural referents unless the context dictates otherwise. The term “or” is meant to be inclusive and means either, any, several, or all of the listed items. The terms “comprises,” “comprising,” “includes,” “including,” or other variations thereof, are intended to cover a non-exclusive inclusion such that a process, method, or product that comprises a list of elements does not necessarily include only those elements but may include other elements not expressly listed or inherent to such a process, method, article, or apparatus. Relative terms, such as “about,” “approximately,” “substantially,” and “generally,” are used to indicate a possible variation of ±10% of a stated or understood value.

The aspects of the present disclosure are susceptible to various modifications and alternative forms. Specific aspects have been shown by way of example in the drawings and are described in detail herein. However, one should note that the examples disclosed herein are presented for the purposes of clarity of discussion and are not intended to limit the scope of the general concepts disclosed to the specific aspects described herein unless expressly limited. As such, the present disclosure is intended to cover all modifications, equivalents, and alternatives of the described aspects in light of the attached drawings and claims.

References in the specification to aspect, example, etc., indicate that the described item may include a particular feature, structure, or characteristic. However, every disclosed aspect may or may not necessarily include that particular feature, structure, or characteristic. Moreover, such phrases are not necessarily referring to the same aspect unless specifically noted. Further, when the discussion described a particular feature, structure, or characteristic in connection with a particular aspect, such feature, structure, or characteristic can be employed in connection with another disclosed aspect whether or not such feature is explicitly described in conjunction with such other disclosed aspect.

Aspects of the disclosure may operate on a particularly created hardware, on firmware, digital signal processors, or on a specially programmed general-purpose computer including a processor operating according to programmed instructions. The terms controller or processor as used herein include microprocessors, microcomputers, Application Specific Integrated Circuits (ASICs), cloud-based servers, and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid-state memory, Random Access Memory (RAM), etc. As will be appreciated by one of skill in the art, the functionality of the program modules may be combined or distributed as desired in various aspects. In addition, the functionality may exist in whole or in part in firmware or hardware equivalents such as integrated circuits, field programmable gate arrays (FPGAs), and the like. Particular data structures may be used to implement more effectively one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that accessible by a computing device. By way of example, and not limitation, computer-readable media may comprise computer storage media and communication media.

Computer storage media means any medium that can store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can communicate computer-readable information. By way of example, and not limitation, communication media may include coaxial cables, fiber-optic cables, air, or any other media suitable for the communication of electrical, optical, Radio Frequency (RF), infrared, acoustic or other types of signals.

The disclosed aspects may be implemented, in some cases, in hardware, firmware, software, or any combination thereof. References made above to FPGAs and other integrated circuits such as voltage regulators, etc., may be replaced with any component that can perform the same functions. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Also, when reference is made in this application to a method having two or more defined steps or operations, the defined steps or operations can be carried out in any order or simultaneously, unless the context excludes those possibilities.

Although specific aspects of the disclosure have been illustrated and described for purposes of illustration, it will be understood that various modifications may be made without departing from the spirit and scope of the disclosure. Accordingly, the disclosure should not be limited except as by the appended claims.

### EXAMPLES

Illustrative examples of the disclosed technologies are provided below. An embodiment of the technologies may include one or more, and any combination of, the examples described below.

Example 1 is a method of determining a characteristic of a device under test (DUT) coupled to a test and measurement instrument, the method including: acquiring a first plurality of measurements for the DUT, where the test and measurement instrument is not configured with the characteristic of the DUT and the first plurality of measurements may include measurements for the characteristic; determining an exponential model of the DUT based on the first plurality of measurements, where the exponential model is representative of behavior of the DUT; acquiring a second plurality of measurements different from the first plurality of measurements, where the second plurality of measurements may include measurements for the characteristic of the DUT; verifying the exponential model based on the second plurality of measurements; and adjusting the behavior of the test and measurement instrument based on the verified exponential model of the DUT.

Example 2 is the method of Example 1, where the exponential model is based on the following equation: ƒ(x)=A+Be^{Cx}.

Example 3 is the method of Example 2, where A, B, and C are determined based on the first plurality of measurements.

Example 4 is the method of any one of Example 1-3, where the exponential model is a continuous function.

Example 5 is the method of any one of Example 1-4, where the first plurality of measurements may include current measurements, each associated with a respective voltage measurement.

Example 6 is the method of any one of Example 1-5, where the second plurality of measurements have a resolution based on the test and measurement instrument.

Example 7 is the method of any one of Example 1-6, where acquiring the second plurality of measurements involves iteratively measuring at a point based on the resolution of the test and measurement instrument.

Example 8 is the method of any one of Example 1-7, where acquiring the second plurality of measurements involves determining the point to be measured based on the exponential model.

Example 9 is the method of any one of Example 1-8, where acquiring the first plurality of measurements involves iteratively measuring at a midpoint between a lower bound and an upper bound.

Example 10 is the method of any one of Example 1-9, where each iteration halves a resolution of a previous measurement.

Example 11 is the method of any one of Example 1-10, where verifying the second plurality of measurements against the exponential model may include: determining at least one of the second plurality of measurements deviates from the exponential model by an amount based on the exponential model; acquiring a third set of measurements; and if the third set of measurements deviates from the exponential model by a deviation amount, indicating an error to a user.

Example 12 is a test and measurement system, including: a test and measurement instrument having one or more ports to connect the test and measurement instrument to a device under test (DUT). The test and measurement system includes memory. The test and measurement system includes one or more processors configured to execute code stored on the memory, where the code causes the one or more processors to: acquire a first plurality of measurements for a parameter of the DUT, where the test and measurement instrument is not configured with the parameter of the DUT; determine an exponential model of the parameter of the DUT based on the first plurality of measurements; acquire a second plurality of measurements for the parameter of the DUT, where the second plurality of measurements are different from the first plurality of measurements; verify the exponential model based on the second plurality of measurements; and adjust behavior of the test and measurement instrument based on the verified exponential model of the DUT.

Example 13 is the test and measurement system of Example 12, where the second plurality of measurements have a resolution based on the test and measurement instrument.

Example 14 is the test and measurement system of Example 12 or Example 13, where the code that causes the one or more processors to acquire the second plurality of measurements may include code that causes the one or more processors to iteratively measure at a point based on the resolution of the test and measurement instrument.

Example 15 is the test and measurement system of any one of Example 12-14, where the code that causes the one or more processors to acquire the second plurality of measurements may include code that causes the one or more processors to determine the point to be measured based on the exponential model.

Example 16 is the test and measurement system of any one of Example 12-15, where the code that causes the one or more processors to acquire the first plurality of measurements may include code that causes the one or more processors to iteratively measuring at a midpoint between a lower bound and an upper bound.

Example 17 is the test and measurement system of any one of Example 12-16, where each iteration halves a resolution of a previous measurement.

Example 18 is a test and measurement system, including: a test and measurement instrument having one or more ports to connect the test and measurement instrument to a device under test (DUT). The test and measurement system includes memory. The test and measurement system includes one or more processors configured to execute code stored on the memory, where the code causes the one or more processors to: determine a model of a parameter of the DUT based on three measurements of the parameter by the test and measurement instrument; verify the model based on a fourth measurement and a fifth measurement of the parameter by the test and measurement instrument; and adjust behavior of the test and measurement instrument for the parameter based on the verified model of the DUT.

Example 19 is the test and measurement system of Example 18, where the code that causes the one or more processors to acquire the fourth and fifth measurements may include code that causes the one or more processors to iteratively measure at a point based on a resolution of the test and measurement instrument.

Example 20 is the test and measurement system of Example 18 or Example 19, where the model is based on the following equation: ƒ(x)=A+Be^{Cx}.

The previously described versions of the disclosed subject matter have many advantages that were either described or would be apparent to a person of ordinary skill. Even so, these advantages or features are not required in all versions of the disclosed apparatus, systems, or methods.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

Although specific examples of the invention have been illustrated and described for purposes of illustration, it will be understood that various modifications may be made without departing from the spirit and scope of the invention. Accordingly, the invention should not be limited except as by the appended claims.

What is claimed is:

1. A method of determining a characteristic of a device under test (DUT) coupled to a test and measurement instrument, the method comprising:
acquiring a first plurality of measurements for the DUT, wherein the test and measurement instrument is not configured with the characteristic of the DUT and the first plurality of measurements comprises measurements for the characteristic;
determining an exponential model of the DUT based on the first plurality of measurements, wherein the exponential model is representative of behavior of the DUT;
acquiring a second plurality of measurements different from the first plurality of measurements, wherein the second plurality of measurements comprises measurements for the characteristic of the DUT;
verifying the exponential model based on the second plurality of measurements; and
adjusting the behavior of the test and measurement instrument based on the verified exponential model of the DUT.

2. The method of claim 1, wherein the exponential model is based on the following equation: ƒ(x)=A+Be^{Cx}.

3. The method of claim 2, wherein A, B, and C are determined based on the first plurality of measurements.

4. The method of claim 2, wherein the exponential model is a continuous function.

5. The method of claim 1, wherein the first plurality of measurements comprises current measurements each associated with a respective voltage measurement.

6. The method of claim 1, wherein the second plurality of measurements have a resolution based on the test and measurement instrument.

7. The method of claim 6, wherein acquiring the second plurality of measurements involves iteratively measuring at a point based on the resolution of the test and measurement instrument.

8. The method of claim 7, wherein acquiring the second plurality of measurements involves determining the point to be measured based on the exponential model.

9. The method of claim 1, wherein acquiring the first plurality of measurements involves iteratively measuring at a midpoint between a lower bound and an upper bound.

10. The method of claim 9, wherein each iteration halves a resolution of a previous measurement.

11. The method of claim 1, wherein verifying the second plurality of measurements against the exponential model comprises:
determining at least one of the second plurality of measurements deviates from the exponential model by an amount based on the exponential model;
acquiring a third set of measurements; and
if the third set of measurements deviates from the exponential model by a deviation amount, indicating an error to a user.

12. A test and measurement system, comprising:
a test and measurement instrument having one or more ports to connect the test and measurement instrument to a device under test (DUT);
memory;
one or more processors configured to execute code stored on the memory, wherein the code causes the one or more processors to:
acquire a first plurality of measurements for a parameter of the DUT, wherein the test and measurement instrument is not configured with the parameter of the DUT;
determine an exponential model of the parameter of the DUT based on the first plurality of measurements;
acquire a second plurality of measurements for the parameter of the DUT, wherein the second plurality of measurements are different from the first plurality of measurements;
verify the exponential model based on the second plurality of measurements; and
adjust behavior of the test and measurement instrument based on the verified exponential model of the DUT.

13. The test and measurement system of claim 12, wherein the second plurality of measurements have a resolution based on the test and measurement instrument.

14. The test and measurement system of claim 13, wherein the code that causes the one or more processors to acquire the second plurality of measurements comprises code that causes the one or more processors to iteratively measure at a point based on the resolution of the test and measurement instrument.

15. The test and measurement system of claim 14, wherein the code that causes the one or more processors to acquire the second plurality of measurements comprises code that causes the one or more processors to determine the point to be measured based on the exponential model.

16. The test and measurement system of claim 12, wherein the code that causes the one or more processors to acquire the first plurality of measurements comprises code that causes the one or more processors to iteratively measuring at a midpoint between a lower bound and an upper bound.

17. The test and measurement system of claim 16, wherein each iteration halves a resolution of a previous measurement.

18. A test and measurement system, comprising:
a test and measurement instrument having one or more ports to connect the test and measurement instrument to a device under test (DUT);
memory;
one or more processors configured to execute code stored on the memory, wherein the code causes the one or more processors to:
determine a model of a parameter of the DUT based on three measurements of the parameter by the test and measurement instrument;
verify the model based on a fourth measurement and a fifth measurement of the parameter by the test and measurement instrument; and
adjust behavior of the test and measurement instrument for the parameter based on the verified model of the DUT.

19. The test and measurement system of claim 18, wherein the code that causes the one or more processors to acquire the fourth and fifth measurements comprises code that causes the one or more processors to iteratively measure at a point based on a resolution of the test and measurement instrument.

20. The test and measurement system of claim 18, wherein the model is based on the following equation: ƒ(x)=A+Be^{Cx}.
